(19) United States
(12) Patent Application Publication
(10) Pub. No.: US 2013/0207231 A1
(43) Pub. Date: Aug. 15, 2013

(54) DIELECTRIC FILM WITH NANOPARTICLES

(71) Applicant: The City University of New York, (US)

(72) Inventors: Limin Huang, New York, NY (US); Stephen O'Brien, New York, NY (US); Shuangyi Liu, New York, NY (US)

(73) Assignee: The City University of New York, New York, NY (US)

(21) Appl. No.: 13/744,726

(22) Filed: Jan. 18, 2013

Related U.S. Application Data
(60) Provisional application No. 61/588,991, filed on Jan. 20, 2012.

(51) Int. Cl. H01L 49/02

(52) U.S. Cl. CPC H01L 28/40
USPC 257/532; 438/386

(57) ABSTRACT

A dielectric film is produced by applying a fluid solvent to a layer of nanoparticles and then polymerizing the solvent between the nanoparticles, or by disposing dielectric nanoparticles in a carrier fluid including a polymerizable substance, applying the resulting fluid to a substrate, and polymerizing a polymerizable substance between the nanoparticles so that the polymerizable substance solidifies to form the dielectric film including the solidified polymerizable substance and the nanoparticles between which the solidified polymerizable substance is disposed. A dielectric film can include nanoparticles and polymer material between at least some of the nanoparticles. The film can have a capacitance change of within 0%-7% over the range 20° C.-125° C. and a dielectric constant between 17.5 and 25 for the range 100 Hz-1 MHz.

### CROSS-REFERENCE TO RELATED APPLICATIONS

This application is a nonprovisional of provisional U.S. Patent Application Ser. No. 61/588,991, filed Jan. 20, 2012, and entitled “Methods for improving dielectric properties of BaTiO3 nanocrystal thin film,” the entirety of which is incorporated herein by reference.

### STATEMENT OF FEDERALLY SPONSORED RESEARCH OR DEVELOPMENT

This invention was made with Government support under Contract No. DE-AR0000114 awarded by the Department of Energy's Advanced Research Projects Agency (ARPA-E).

### FIELD OF THE INVENTION

The present application relates to dielectric thin films and methods of preparing them.

### BACKGROUND

High-dielectric-constant thin films have shown wide applications in embedded capacitors, multilayer capacitors, gate dielectrics for organic field effect transistor, memory and power storage devices. For example, with the miniaturization of modern electronic devices more and more discrete surface mounted passive components (such as capacitors, resistors and inductors) are being converted into embedded ones, which are placed as thin films between interconnecting layers of a printed wiring board using an embedded technology. Such embedded capacitors require dielectric thin films with stable and high dielectric constants in a wide frequency and temperature range, high dielectric strength, low dielectric loss, low leakage current, as well as a low processing temperature. BaTiO₃-based materials featuring high dielectric constants and low intrinsic dielectric loss in a wide frequency range have been widely used as an inorganic high-κ dielectric component. However, high-κ thin films composed of individual nanocrystals can exhibit low mechanical strength and porosity that is detrimental to their dielectric performance.

### BRIEF DESCRIPTION OF THE INVENTION

With the development of synthesis methods for various monodisperse, highly crystalline nanocrystals, a solution processing based on the self-assembly of nanocrystal building blocks becomes an attractive procedure to fabricate various functional thin films at room temperature. Solution processing differs from traditional thin film fabrication based on various physical or chemical procedures such as pulsed laser deposition, metal-organic chemical vapor deposition (MOCVD), sputtering or sol-gel process that usually involve high temperature processing necessary for crystallization (>500° C.), and/or sophisticated instrumentation. The solution process also has advantages of scalability and is low temperature process, which is, especially, advantageous for flexible substrate/flexible electronics where process temperatures are very limited.

However, pure high-x nanocrystal thin films have some problems. First, the self-packing of pure barium titanate (BT) nanocrystals at room temperature forms interparticle void space if no further sintering process (>1000° C.) is applied for film densification. The thin film normally presents a porous structure of about ˜20-30 vol % empty space. That space can be occupied by the air, which has a relatively low dielectric constant (˜1) and breakdown voltage (or dielectric strength) (˜3 V/μm) compared to the BT materials. The hydrophilic nature of nanocrystals and the porous thin film also can attract moisture from the air, causing a dramatic change in dielectric constant and dielectric loss over a wide frequency range. Secondly, since nanocrystals in a thin film are loosely contacted with one another, only weak (if any) interactions exist among the neighboring nanocrystals, which may compromise the synergistic effect of nanocrystals for enhanced dielectric properties. The corresponding thin film has relatively low mechanical strength because of the loose interconnection of nanocrystals. The above factors are disadvantageous to the application of high-κ thin film composed of individual nanocrystals.

A nanocrystal thin film can be treated as composite filler/host system, where the filler is high-κ nanocrystals. For a pure nanocrystal thin film, the host can be regarded as the air that stays within interparticle voids. An effective dielectric constant of the 0-3 composite thin film (granular fillers and host matrix) can be predicted by a modified Kerner model with correction of volume fraction from 0-1, which is expressed as:

$${ɛ}_{eff} = \frac{{ɛ}_{h} \cdot {f}_{h} + {ɛ}_{f} \cdot {f}_{f} \cdot ( A ) ( B )}{{f}_{h} + {f}_{f} \cdot ( A ) ( B )} , where \\ A = \frac{3 {ɛ}_{h}}{{ɛ}_{f} + 2 {ɛ}_{h}} and B = 1 + \frac{3 {f}_{f} \cdot ( {ɛ}_{f} - {ɛ}_{h} )}{{ɛ}_{f} + 2 {ɛ}_{h}} , \qquad ( 1 )$$

∈ₕ, fₕ and ∈_{f}, f_{f} are the dielectric constants and volume fractions of the host and filler, respectively. The kerner and modified models were obtained from Maxwell electrostatic theories and related boundary conditions' The effective dielectric constant of the composited thin film is thus independent of the size of the granular filler. Hence, for comparing the effects of the dielectric constants of filler and matrix with volume fraction of the fillers, the equation 1 is expressed as:

$$\frac{{ɛ}_{eff}}{{ɛ}_{h}} = \frac{{ɛ}^{2} + 4 ɛ + 4 + 2 {v}_{f} {ɛ}^{2} + 2 ɛ {v}_{f} - 4 {v}_{f} + 9 ɛ {v}_{f}^{2} ( ɛ - 1 )}{{ɛ}^{2} + 4 ɛ + 4 - {v}_{f} {ɛ}^{2} - ɛ {v}_{f} + 2 {v}_{f} + 9 {v}_{f}^{2} ( ɛ - 1 )} , \\ where \\ ɛ = {ɛ}_{f} / {ɛ}_{h} . \qquad ( 2 )$$

This shows that a way to increase the effective dielectric constant is to increase the volume fraction of the filler (BT). However, the limitation of closed packing of homogeneous hard spherical particles is about 0.74, i.e. effective dielectric constant cannot be arbitrarily increased solely through increasing packing density. In addition, a third phase (voids) is often present in the real fabrication process of composited film. Equations that can be used to predict effective dielectric constant of composited film with present of three phases are:

∈_{eff}=∈ₕ+v(∈ᵥ−∈ₕ)aᵥ+v_{f}(∈_{f}−∈ₕ)a_{f}, (3a)

aᵣ=1−s[(∈ᵣ−∈_{eff})⁻¹∈_{eff}+s]⁻¹,r=v,f, (3b)

where aᵣ is electric field concentration factor for corresponding r phase, ∈ᵥ, vᵥ, are dielectric constant and volume fraction of the void. These equations show the importance of the increasing the dielectric constant of the matrix as well as the filler.

A way to increase the effective dielectric constant is to increase the packing density of nanocrystals and to infiltrate the interparticle void space with some inorganic or polymer species with higher dielectric constants. Improving interconnection/interaction between nanocrystals can also improve properties because it can further increase the density of polarizable dipoles in thin films.

Polymer/nanocrystal composites have received much attention because they combine high dielectric constants of the inorganic nanocrystal fillers and the high dielectric strength of the polymer host. The dielectric constant of the nanocomposite thin film increases with the increase of the volume ratio of the inorganic filler. However, the dielectric constant may reach a maximum at a certain volume ratio (50-60%) and decrease with further increasing the volume ratio, showing discrepancy from the modified Kerner model probably because the porous structure from the close-packing of nanocrystals cannot be filled by a polymer with large molecular volume. Accordingly, there is a continuing need for an improved dielectric film, and for ways of manufacturing such films.

Different from conventional polymer/nanocrystal composites, various aspects described herein use a precursor (such as monomer, or inorganic high-κ precursor) with small molecular weight and size that can easily infiltrate the thin film and fill up the voids. The void space is then filled with a polymer after in-situ polymerization of the monomer molecules or inorganic high-κ materials. Other aspects include dissolving or suspending nanoparticles in a monomer or other polymerizable solvent and polymerizing in-situ.

Various aspects provide new ways of preparing dense and high performance nanocrystal thin films, or such films. Unlike the preparation of conventional polymer/nanocrystal composite thin films, various aspects use a precursor (such as furfural alcohol as a monomer, or inorganic high-κ precursor solution) with small molecular sizes that can easily infiltrate porous nanocrystal thin films. The corresponding interparticle void space is filled with a polymer after in-situ polymerization of its monomer or inorganic high-κ materials, providing improved dielectric properties and mechanical strength to the composite thin films.

In various aspects, furfural alcohol (FA) is used. FA shows good affinity to BaSrTiO₃ (BST) nanocrystals and good compatibility with various solvents. FA can be used as an effective void filler and a polymerizable solvent. In addition, BST nanocrystals can be readily dispersed in FA to form a stable suspension, which is suitable for thin film fabrication using spin-coating or printing process.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 shows capacitance data and FIG. 2 shows percent-capacitance-change data for measured spin-coated capacitors;

FIG. 3 shows capacitance data and FIG. 4 shows percent-capacitance-change data for measured spray-coated capacitors;

FIG. 5 shows dielectric-constant and dielectric-loss data for a BST thin film before FA treatment;

FIG. 6 shows dielectric-constant and dielectric-loss data for a BST thin film after FA treatment;

FIGS. 7 and 8 show flowcharts of methods of producing a dielectric film according to various aspects;

FIG. 9 is an SEM micrograph of a cross-section of a multilayer dielectric film according to various aspects; and

FIG. 10 is a representation of a cross-section of a dielectric film according to various aspects.

The attached drawings are for purposes of illustration and are not necessarily to scale.

### DETAILED DESCRIPTION OF THE INVENTION

Various aspects described herein are ways of preparing dense and high performance nanocrystal thin films that show enhanced dielectric properties and improved mechanical strength. High dielectric constant (k) thin films have wide applications in modern electronics such as embedded capacitors, multilayer capacitors, gate dielectrics for organic field effect transistors, memory and power storage devices.

According to various aspects, dielectric nanoparticles are materials purposed for use as dielectric components within a dielectric film. An individual dielectric nanoparticle has dimensions, e.g., length, diameter or other feature in the range 1-1000 nm. For example, the dielectric nanoparticles can be high-dielectric-constant oxides that have been synthesized in the form of nanoparticles. In various aspects, dielectric nanoparticles include barium strontium titanate (BaSrTiO₃) or barium titanate (BaTiO₃). Dielectric nanoparticles can also include perovskite materials, e.g., CaTiO₃ or other compounds forming crystal lattice structures similar to CaTiO₃, e.g., PbTiO₃ or Pb(Ti,Zr)O₃.

Various aspects described herein use furfural alcohol (FA) as a void filler as well as a polymerizable solvent that is compatible with BST nanocrystals and various solvents. Advantages of FA include (1) FA is miscible with water, and is soluble in common organic solvents such as alcohol; (2) FA molecules have strong affinity with BT(BST) nanocrystal surface, and the nanocrystals can be readily dispersed in FA to form a stable solution, and it can effectively infiltrate the interparticle voids; (3) FA can be easily polymerized in situ into a solid resin (poly(furfuryl alcohol)) upon treatment with heat and/or acid catalysts (such as p-toluenesulfonic acid), providing a passivating layer to a nanocrystal surface and holding the nanocrystals together. As a result, the mechanical strength of thin films can be further increased; (4) polymer PFA has stable and relatively high dielectric constant of ˜7 and low dielectric loss in a wide frequency range; (5) it is hydrophilic when monomeric and hydrophobic when cross-linked, so it may act as a moisture barrier.

The chemical structure of furfural alcohol (FA) is:

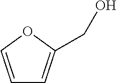

After polymerization by heat, and optionally with an acid catalyst, polyfurfural alcohol (PFA) is formed:

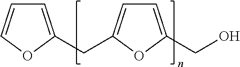

The polymerization reaction also liberates n H₂O.

Three procedures/formulation have been developed for device fabrication, which are (1) FA as a void filler based on an infiltration-polymerization process. It is basically used on a pre-existing nanocrystal thin film for modification; (2) BT(BST)/EtOH+FA/PA (ethanol and FA as co-solvent), having good surface wettability and thus suitable for spin-coating process; (3) BT(BST)/FA solution (FA as only solvent), suitable as an ink for printing process.

In various aspects, an infiltration-polymerization process is used. An example was tested according to various aspects. First, BST nanoparticles solution (20 mg/mL in ethanol) was spin-coated onto a substrate to generate a thin film with a thickness of 200-400 nm. The film was dried at 80° C. on a hot plate to remove the remaining ethanol solution. Once dried, the film was then immersed in a FA solvent. After being infiltrated for 30 min at room temperature, the film was slowly pulled out of the solution, and was dried on a hot plate at a temperature of 60-90° C. for 0.5 h to initiate the polymerization followed by 120° C. for 5 h for complete polymerization.

Another example was tested according to various aspects. The infiltration-polymerization process was realized via a vapor phase. First, ethanol solution of BST nanocrystals and acid catalyst PA were mixed with the molar concentration of PA at 0.025M. The mixture solution was spin-coated onto a substrate to generate a thin film containing PA catalyst, which was dried at 80° C. to get rid of the ethanol solvent. Then, the PA acid-containing BST thin film was kept with a FA solvent in a sealed container. The container was heated at 90° C. for 4 hrs, where FA solvent was vaporized and polymerized within the thin film with the presence of PA acid catalyst.

SEM images showed that the interparticle void space in a pure BST thin film has been greatly reduced after the FA infiltration and polymerization.PFA does not necessarily form an additional top layer (as parylene does) that might, if it formed, decrease the dielectric constant of the thin film.

Tapping mode AFM results showed lower RMS and smaller surface area difference (i.e. difference between the image's three-dimensional surface area and two-dimensional projected surface area) for a 30 nm BST nanocrystal thin film after FA infiltration and polymerization. The BST/PFA thin film surface becomes smoother and shows lower surface roughness after processing. Data are given in Table 1:

TABLE 1
Surface roughness of BST thin films before and after FA treatment.

| | Image Surface Area | | |
|---|---|---|---|
| | Difference | RMS | Image Ra |
| Pure BST 30 nm | 43.7% | 22.6 | 17.8 |
| BST 30 nm/PFA | 39.1% | 16.2 | 12.9 |

In various aspects, a co-solvent process is used, e.g., BT(BST)/EtOH with FA/PA (ethanol and FA as co-solvents). An example was tested according to various aspects. 1000 mL of furfural alcohol (FA) was first mixed with 25 mL of p-toluenesulfonic acid (or PA, 0.025M in ethanol solvent) which is used as an acid catalyst (concentration: 6.25×10⁻⁴M). Then, 400 mL of BST nanocrystal solution (ethanol as solvent, 20 mg/mL) was mixed with 50-100 mL of the above FA solution. The whole mixture solution was shaken for 5 min prior to use. The BST/FA(PA)/EtOH solution showed good wettability and dispersed well on substrate surface. When the nanocrystal solution was drop coated or spin-coated on a substrate, the nanocrystals were self-assembled to a closely packed thin film with the evaporation of low-boiling-point solvent ethanol (78° C.) while high-boiling-point solvent FA (170° C.) was trapped in the nanocrystal thin film. The polymerization took places by heating at an initial temperature of 60° C. followed by 120° C. for a complete polymerization.

In various aspects, a polymerizable solvent is used, e.g., BT(BST) with FA as only solvent. FA molecules have strong affinity with BT(BST) nanocrystals because of their abundant surface hydroxyl groups. An example was tested according to various aspects. BT(BST) nanocrystals were well dispersed in FA solvent with a concentration of 20 mg/mL using a regular sonicator to afford a stable solution. Solvent FA has higher surface tension (38.2 mN/m) and higher viscosity (4.62 mPa·S) than ethanol solution (22 mN/m and 1.074 mPa·S, respectively), and lower surface tension than water (72 mN/m). Thus, the FA solution of nanocrystals is more suitable as an ink for printing. FA was polymerized upon heating at an initiate temperature of 60° C. followed by 120° C. for full polymerization.

SEM imagery showed that nanocrystal/PFA formed a close-packed, uniform thin film with no phase separation, and was denser than pure BST thin film although interparticle voids are not completely eliminated.

Dielectric properties of exemplary BST thin films are now discussed.

A BST thin film composed of individual BST nanocrystals can absorb moisture from the environment because of its high porosity and its hydrophilic nature. Capacitance and dielectric loss can both change with increasing frequency due to variable contribution from space charges or absorbents (water molecules) at different frequencies. Much higher capacitance and dielectric loss can be observed at low frequency (100 Hz) due to leakage current (i.e. mobile carriers associated with free charges, defects, and pinholes, etc). In various aspects, the nanocrystal surface is advantageously passivated and the interparticle voids filled.

Prior schemes use parylene coating as a void filler as well as a moisture barrier. Parylene film can conform closely to surfaces, including edges, flat surfaces, or corners when all sides of surface were exposed simultaneously to a polymerizing gas (active monomer gas). Since the coating process takes place at ambient temperature (although parylene precursor (dimer) is decomposed to monomer and vaporized at a high temperature of 550° C.), parylene shows limited capability of penetrating through the porous thin film and filling up the void space. Instead, the parylene polymer is almost deposited on top of the film to form a dense and insulating layer, causing the reduction of overall dielectric constant. The calculation based on a layered structure model is well consistent with the experimental results, confirming less parylene infiltration during the coating process.

With the modification with polymer PFA, BST nanocrystal surface is passivated with reduced defects/pinholes and fewer mobile carriers in the film. A tested BST/PFA thin film showed a lower capacitance drop and dielectric loss after FA treatment than before, measured from 100 Hz-10 MHz. Capacitance remained stable across this range after FA treatment. In Table 2, below, a typical capacitance density is 0.51 nF/mm² for a 300-nm-thick thin film at a frequency of 1 MHz, while it is 0.45 nF/mm² for a pure BST thin film before the FA treatment. The increase in capacitance density compared with that of pure BST suggests that the FA solvent has successfully infiltrated the void space and the partial empty space was replaced with PFA with high dielectric constant, which results in the increase of effective dielectric constant of the thin film. On the contrary, parylene tends to stay on top of BST thin film, which only decreases the capacitance density and therefore the dielectric constant of the film (Table 2). In addition, the dielectric loss also remains low (˜0.04-0.05) up to a frequency of 1 MHz as compared with a high loss for the pure BST thin film (Table 2). It should be pointed out that the increase of dielectric loss at high frequency above 100 KHz is due to relatively high actual series resistance which includes the resistance in electrodes and the contact resistance between a measuring probe and a bottom electrode embedded in dielectric thin films.

TABLE 2

| | Capacitance | Dielectric | Dielectric | | |
|---|---|---|---|---|---|
| | density | constant | constant of | Dielectric | |
| Sample | (nF/mm²) | of thin film | nanoparticles | loss | Comments |
| BST(80 nm)/ | 0.50 | 7.3 | | 0.035 | Decrease of k fits |
| Parylene(50 nm) | | | | | the model of layer |
| BST(300 nm)/ | 0.26 | 10.4 | | 0.039 | structure, |
| Parylene(50 nm) | | | | | suggesting top |
| | | | | | layer formation |
| | | | | | with less polymer |
| | | | | | infiltration |
| Pure | 0.45 | 15 | ~57 | 0.24 | Reference |
| BST(300 nm) | | | | | |
| BST/PFA (by | 0.51 | 17.3 | | 0.045 | Increase of k |
| infiltration/ | 0.58 | 19.4 | | 0.098* | suggesting FA and |
| polymerization, | | | | | PFA infiltration |
| 300 nm thick) | | | | | among |
| BST/PFA (by | 0.12 | 18.9 | | 0.050 | nanocrystals |
| cast coating, FA | | | | | |
| as solvent, ~1.4 | | | | | |
| μm thick) | | | | | |

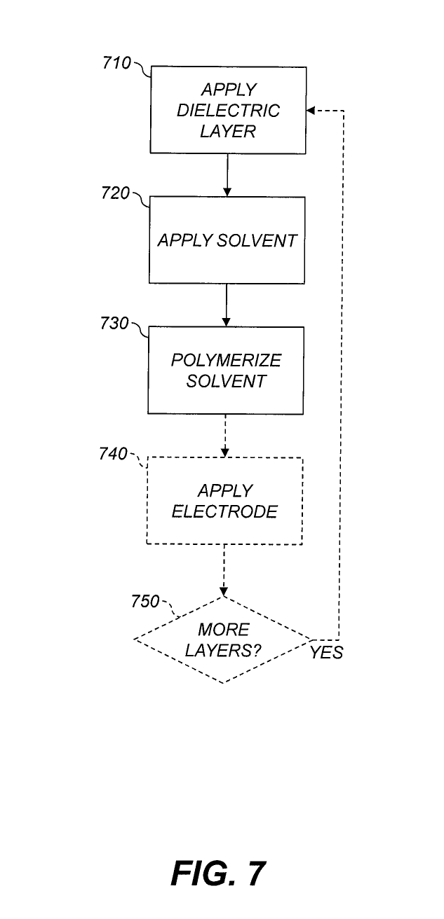

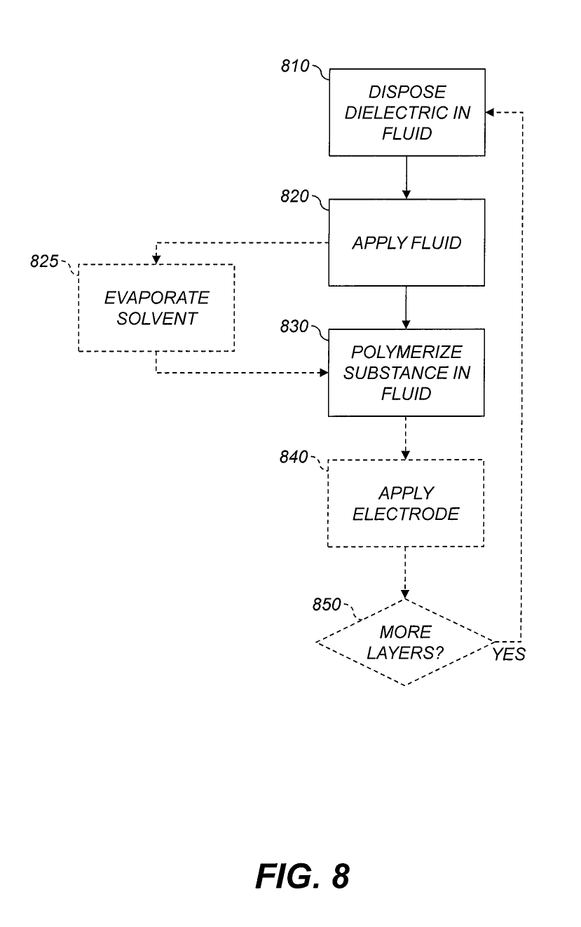

BT(BST) thin films with a crystal size of 8-12 nm have no hysteresis loops in a series of polarization versus electric field (P-E) curves conducted on a Radiant Precision Workstation. The polarization behavior of nanocrystal thin films was studied by Piezoelectric Force Microscopy (PFM). PFM measures the mechanical response when an electrical voltage is applied to the sample surface with a conductive tip of an AFM. In response to the electrical stimulus, the sample below the tip then locally expands or contracts, which can be detected and measured in terms of piezo response properties. For BST 30 nm nanocrystal thin films before and after FA infiltration/polymerization, the piezo response phase as a function of tip bias showed no hysteresis loop and little ferroelectric response (compared with a control image for non-ferroelectric Si wafer). A significant vibrating response can be observed on the BST/PFA thin film, while it cannot be found on a pure BST thin film (FIG. 7). It suggests that there are some interactions between the nanocrystals in the BST/PFA, while the nanocrystals are isolated in the pure BST thin film. The presence of particle interaction has been confirmed with a multi-color pattern based on a piezo response signal that expands and contracts in-plane with applied electric field (FIG. 8). When nanocrystals are interconnected, the local in-plane deformation of one individual nanocrystal in response to a tip bias can be transferred to neighboring nanocrystals via possible polymer binding, affecting the piezo response of the neighboring nanocrystals. A multi-color pattern represents for various interactions between the nanocrystals after FA polymerization, as compared with a single-color pattern for a BST film without FA treatment.

A bulk ferroelectric BST normally show a typical hysteresis loop in its polarization curve and a phase transition around its Curie temperature (120° C.), which result in a significant variation in dielectric constant with temperature change. Since there is no hysteresis loop in the BST thin film when the crystal is downsized to below 30 nm in diameter, the nanocrystal thin film can present a stable dielectric constant as a function of temperature.

In addition to the above FA/PFA void filler, inorganic precursors with good compatibility with BT(BST) nanocrystals can also be used as fillers. There are several options of inorganic precursor solution that can be used to infiltrate the interparticle void space. The inorganic precursor can also be regarded as a glue to hold the nanocrystals together as well as a void filler.

In an example, a stable BT precursor solution (BTP) was prepared as follows: 0.16 g Ba(iPr)₂ was dissolved in 15 mL 2-methoxyethanol to form a clear solution, then 0.185 mL Ti(iPr)₄ was added to the above solution. 2-methoxyethanol is reported to have strong affinity to the metal oxide surface. The yellowish solution was stirred at 60-80° C. for 6 h to afford a stable BT precursor solution (˜10 mg/mL).

In another example, a BST precursor solution using ethanol as only solvent can be prepared by refluxing a mixture of 0.310 g Ba(iPr)₂, 0.104 g Sr(iPr)₂, and 0.5 mL Ti(iPr)₄ in 40 mL EtOH/1 mL H₂O solvent at 78° C. for 3 h. A clear BST precursor solution (˜10 mg/mL) was obtained.

Other inorganic high-κ precursor solution such as TiO₂ and HfO₂ precursor solution, can also be prepared by mixing Ti(iPr)₄ or hafnium n-butaoxide with ethanol.

A stable and clear BST/BTP solution was prepared by mixing BT(BST) nanocrystal ethanol solution (25 mg/mL) with the above BT(BST) precursor solution with a volume ratio of 2:1-1:1. The solution was then spin-coated on a substrate (Si wafer, glass, or flexible plastic) at a rate of 1500 rpm. The thin film was baked at 80-120° C. overnight to afford a stable BST nanocrystal/BST amorphous nanocomposite thin film (BST/BSTa, a-amorphous).

SEM images showed that the interparticle voids were significantly reduced in number or size for the nanocomposite BST/BSTa thin film. The electrical measurement shows that the dielectric constant increases compared with pure BST thin film, while dielectric loss is a bit higher in the wide frequency range probably because of the space charges.

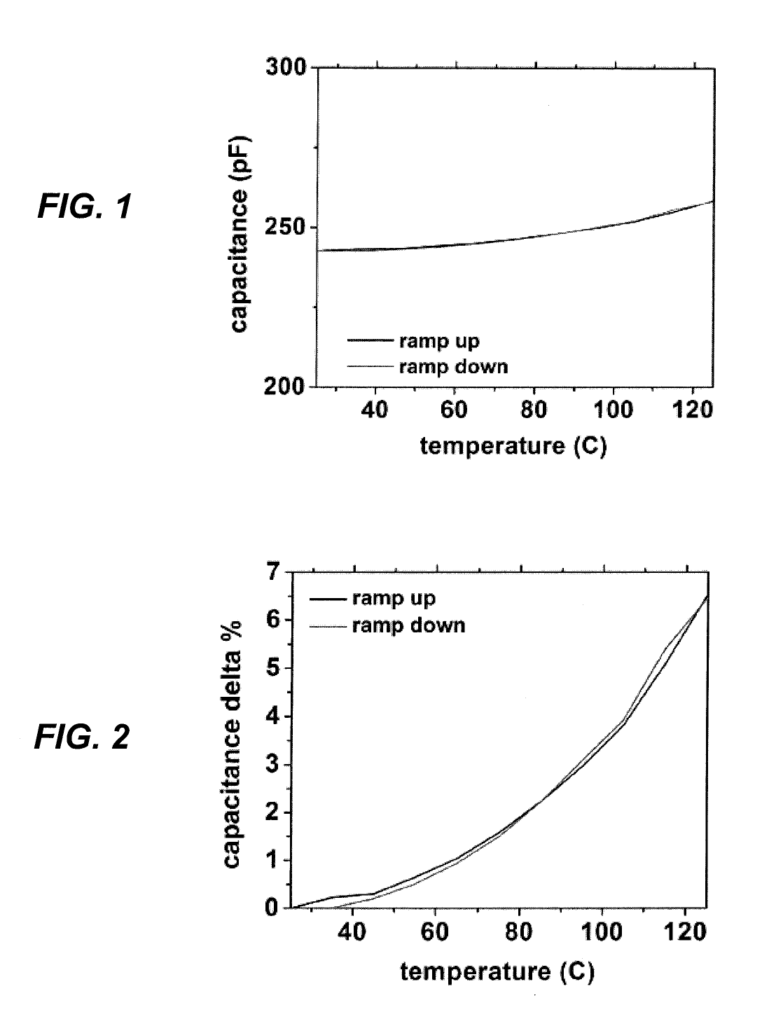

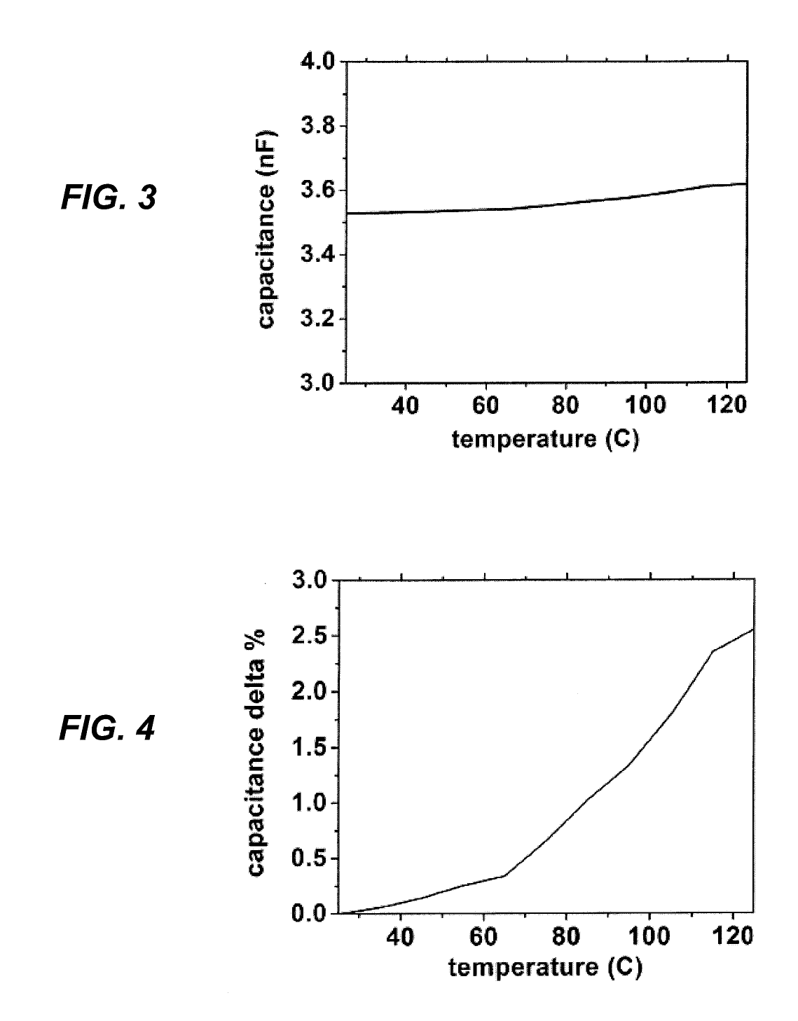

Various capacitors were constructed. The dielectrics of those capacitors were constructed according to various aspects described herein. Measurements were then taken. In one test series, elevated temperature test of capacitors was conducted on both spin-coated capacitors (1×1 mm²) and spray-coated capacitors (2×2 mm²). The capacitance of the devices was measured at 1 MHz at elevated temperature starting from 25° C. to 125° C. with 10° C. increments. The samples were placed on a heater with temperature control that has 1° C. precision, and the capacitance measurements were taken with the Agilent 4294 impedance analyzer. The temperature dependent capacitance data for spin coated and spray coated capacitors are shown in FIGS. 1 and 2. The capacitance changes (%) for both capacitors are shown in FIGS. 3 and 4. The capacitance increases with temperature. The spin coated capacitor shows a 6.5% increase and the spray coated capacitor shows 2.5% increase in capacitance over the temperature range from 25° C. to 125° C. Based on these measurements, there is no phase transition observed within the 25° C. to 125° C. temperature range, and capacitance is quite stable over this range.

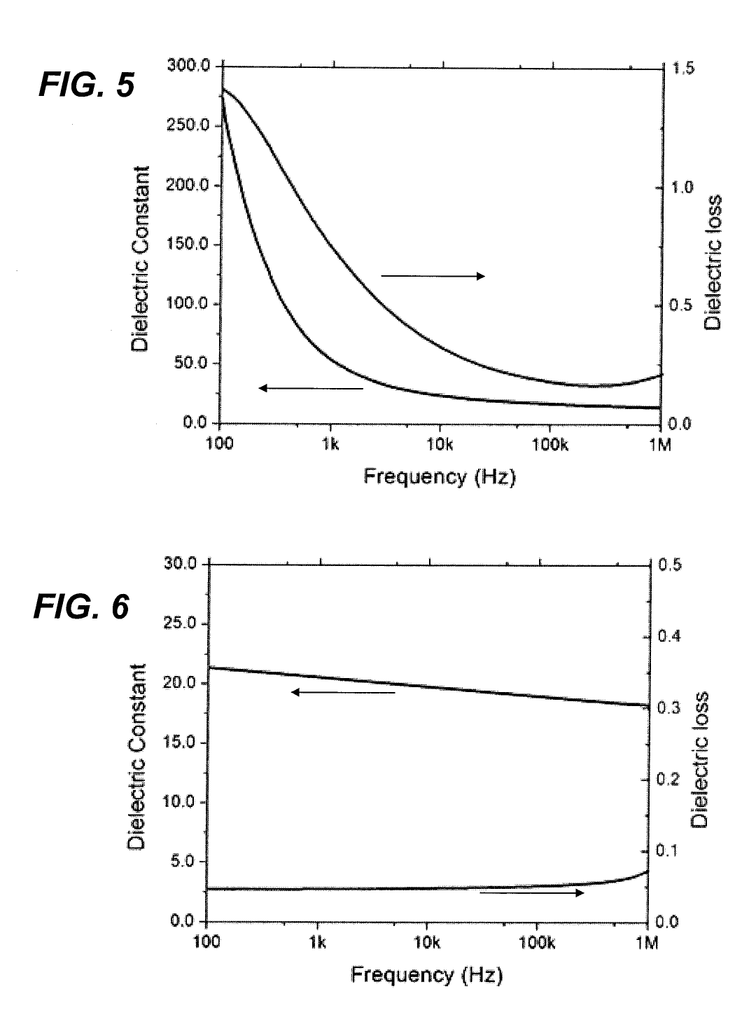

A pure BST nanocrystal thin film can absorb moisture because of its high porosity and its hydrophilic nature. FIG. 5 shows changes of both capacitance (or dielectric constant) and dielectric loss over a wide frequency range (100 Hz-1 MHz). Much higher capacitance (or dielectric constant) and dielectric loss are observed at low frequency (<100 Hz) due to the contribution from interfacial polarizations (space charges) and surface absorbents (e.g. water molecules), whose polarization direction cannot follow up the change of alternative current (ac) electric field, causing dramatic decrease in dielectric constant and loss with increasing frequency. The dielectric constant and dielectric loss start to smooth out at high frequency (>100 MHz), showing the intrinsic dielectric property of BST nanocrystals.

On the other hand, as SEM data indicate, the FA molecule can infiltrate BST nanocrystal thin film and fill up the intercrystal void space because of its strong affinity to the nanocrystals and its small molecular volume. With the in situ polymerization of FA upon heat treatment, BST nanocrystal surface can be passivated and the void space can be filled up as well. Different from the pure BST thin film, the BST/PFA thin film (FIG. 6) shows lower but stable capacitance (or dielectric constant) and dielectric loss starting at a low frequency of 100 Hz, and remains steady up to a high frequency of 1 MHz. In Table 3, below, a typical capacitance density is 0.58 nF/mm² for a 300-nm-thick thin film (or a dielectric constant of ˜19.6) at a frequency of 1 MHz, while it is 0.45 nF/mm² (or a dielectric constant of ˜15) for a pure BST thin film before the FA treatment. The increase in the capacitance density (or the effective dielectric constant) of BST nanocrystal thin film suggests that the intercrystal void space has been successfully infiltrated and occupied with FA molecules, which was then converted into the polymerized form (PFA) with high dielectric constant after in-situ polymerization with heating. In addition, the dielectric loss also remains low (˜0.04-0.05) up to a frequency of 1 MHz as compared with a high loss for the pure BST thin film (Table 3), and the dielectric loss can be further reduced when the sample was well sealed to avoid moisture uptake.

TABLE 3
Comparison of dielectric properties of BST (~8 nm) nanocrystal
thin films with different polymer modification (taken at 1 MHz).

| | Effective | | | Volume |
|---|---|---|---|---|
| | dielectric | | Dielectric | fraction of |
| | constant of | Dielectric | constant of | nanocrystals |
| Sample | thin film | loss | nanocrystals | (%) |
| BST(8 nm)/ | 10.4 | 0.039 | | |
| Parylene | | | | |
| Pure BST(8 nm) | 15 | 0.24 | ~57* | ~68 |
| BST 8 nm/PFA | 19.4 | 0.045 | | ~68 |
| (by infiltration/ | | | | |
| polymerization, | | | | |
| 300 nm thick) | | | | |
| BST/PFA (by | 27 | 0.05 | | ~60* |
| spin-coating), | | | | |
| 500 nm | | | | |

*estimated based on modified Kerner model.

FIG. 7 shows methods of producing a dielectric film according to various aspects. Further details of various aspects are given above with reference to “infiltration” methods. In step 710, a layer of dielectric nanoparticles is applied to a substrate.

In step 720, a fluid solvent is applied to the layer on the substrate. The nanoparticles are soluble in the fluid solvent. The solvent can be liquid or vapor. The applying can include disposing the layer on the substrate in a volume containing the solvent, e.g., by immersing the substrate and layer in the solvent, or by placing the substrate and layer in a chamber holding a mass of the gaseous solvent. As a result of the application, at least some of the solvent is disposed between at least some of the nanoparticles.

In step 730, the solvent between the nanoparticles is polymerized. Solvent not between the nanoparticles can be polymerized, or not. It is not required that absolutely 100% of the mass of solvent infiltrating the nanoparticle layer polymerizes. By polymerizing, the solvent solidifies to form the dielectric film including the solidified solvent and the nanoparticles between which the solidified solvent is disposed. The polymerized (solidified) solvent forms the host for the nanoparticle fillers, as discussed above. For example, the fluid solvent can include furfural alcohol (FA) and the solidified solvent can include polyfurfural alcohol (PFA). The PFA can serve as the host in the dielectric film. Step 730 can include heating at 120° C. or 90° C.

In various aspects, the substrate includes an electrode to which the fluid solvent is applied. In step 740, an electrode is applied to the side of the film opposite the substrate, e.g., by printing or evaporating electrode material such as aluminum onto the dielectric film. This is done after polymerizing step 730. As a result, the dielectric film is a capacitor dielectric.

In various aspects, steps 710, 720, 730, and 740 are repeated to provide a multilayer dielectric structure with embedded conductors. This is represented by More layers? decision step 750.

In various aspects, e.g., as discussed above with reference to Table 2, the resulting dielectric film has a capacitance density greater than the capacitance density of a pure thin film of the dielectric nanoparticles.

FIG. 8 shows methods of producing a dielectric film according to various aspects. Various of these aspects are discussed above with respect to solvents and co-solvents. In step 810, dielectric nanoparticles are disposed in a carrier fluid. Disposing can include dissolving, dispersing, or suspending, and the carrier fluid and nanoparticles can form a solution, dispersion, or colloid. The carrier fluid can include multiple solvents. The result of disposing particles in carrier is referred to as a first fluid. The carrier fluid includes a polymerizable substance.

In step 820, a layer of the first fluid is applied to a substrate. Thus at least some of the nanoparticles are disposed over the substrate and have at least some of the polymerizable substance between them.

In step 830, the polymerizable substance between the nanoparticles is polymerized so that the polymerizable substance solidifies to form the dielectric film including the solidified polymerizable substance. The term “solidified polymerizable substance” does not require that the substance be susceptible to further polymerization. The dielectric film also includes the nanoparticles between which the solidified polymerizable substance is disposed. In an example, the carrier fluid includes furfural alcohol (the polymerizable substance) and the solidified polymerizable substance includes polyfurfural alcohol. In various aspects, the carrier fluid includes only the polymerizable substance, e.g., FA, and the carrier fluid polymerizes to form the solidified polymerizable substance, e.g., PFA.

In various aspects, step 825 includes evaporating the solvent in the carrier fluid (e.g., ethanol) before polymerizing the polymerizable substance (e.g., FA).

In various aspects, the substrate includes an electrode to which the first fluid is applied. In step 840, an electrode is applied to the side of the film opposite the substrate after the polymerizing step so that the dielectric film is a capacitor dielectric. Electrode-application aspects described above with reference to FIG. 7 can be used. The applying-electrode step can include printing or evaporating electrode material onto the dielectric film. Steps 820, optionally 825, 830, and 840 can be repeated to provide a multilayer dielectric structure with embedded conductors (decision step 850).

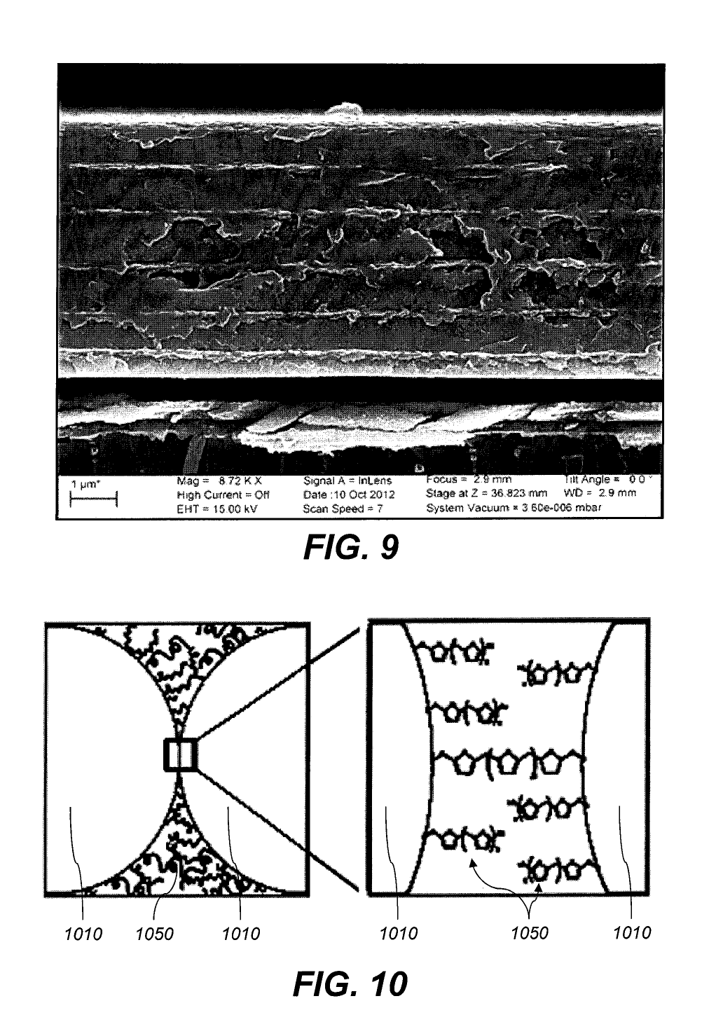

FIG. 9 is an SEM image of a cross-section of a multilayer dielectric film. FIG. 10 is a representation of a cross-section of a dielectric film comprising nanoparticles and polymer material between at least some of the nanoparticles. Nanoparticles 1010 have polymer 1050 chains between them. The film has a capacitance change of within 0%-7% over the range 20° C.-125° C. and a dielectric constant between 17.5 and 25 for the range 100 Hz-1 MHz, as discussed above with reference to FIGS. 1-6. This advantageously provides higher dielectric constant than common COG-class dielectrics, better temperature stability than X7R or Y5V dielectrics, and more flexibility in designing capacitors to fit a particular form factor than conventional ceramics. E.g., polymer can be applied in liquid form to fit take on any desired shape when polymerized.

In various aspects, such as the example shown in FIG. 9, electrodes are disposed on opposite sides of the dielectric film.

In various aspects, the layer thickness of a single layer of dielectric film is 200-400 nm, or approximately 1.4 μm. In various aspects, the nanocrystals have diameters of approximately 30 nm.

In various aspects, rather than depositing electrodes on the dielectric film, the film is formed tens of microns thick. The film is then peeled off a host substrate and disposed between electrode substrates.

The invention is inclusive of combinations of the aspects described herein. References to “a particular aspect” and the like refer to features that are present in at least one aspect of the invention. Separate references to “an aspect” or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

1. A method of producing a dielectric film, the method comprising:
applying a layer of dielectric nanoparticles to a substrate;
applying a fluid solvent in which the nanoparticles are soluble to the layer on the substrate, so that at least some of the solvent is disposed between at least some of the nanoparticles; and
polymerizing the solvent between the nanoparticles so that the solvent solidifies to form the dielectric film including the solidified solvent and the nanoparticles between which the solidified solvent is disposed.

2. The method according to claim 1, wherein the substrate includes an electrode to which the fluid solvent is applied, the method further including applying an electrode to a side of the dielectric film opposite the substrate after the polymerizing step so that the dielectric film is a capacitor dielectric.

3. The method according to claim 2, further including repeating the applying-layer, applying-fluid, polymerizing, and applying-electrode steps to provide a multilayer dielectric structure with embedded conductors.

4. The method according to claim 2, wherein the applying-electrode step includes printing or evaporating electrode material onto the dielectric film.

5. The method according to claim 1, wherein the fluid solvent includes furfural alcohol and the solidified solvent includes polyfurfural alcohol.

6. The method according to claim 1, wherein the polymerization step includes heating at 120° C. or 90° C.

7. The method according to claim 1, wherein the dielectric film has a capacitance density that is greater than a capacitance density of a pure thin film of the dielectric nanoparticles.

8. A method of producing a dielectric film, the method comprising:
disposing dielectric nanoparticles in a carrier fluid to form a first fluid, wherein the carrier fluid includes a polymerizable substance;
applying a layer of the first fluid to a substrate, so that at least some of the nanoparticles are disposed over the substrate and have at least some of the polymerizable substance between the nanoparticles; and
polymerizing the polymerizable substance between the nanoparticles so that the polymerizable substance solidifies to form the dielectric film including the solidified polymerizable substance and the nanoparticles between which the solidified polymerizable substance is disposed.

9. The method according to claim 8, wherein the carrier fluid includes furfural alcohol and the solidified polymerizable substance includes polyfurfural alcohol.

10. The method according to claim 8, wherein the carrier fluid further includes a solvent, and the method further includes evaporating the solvent before polymerizing the polymerizable substance.

11. The method according to claim 8, wherein the polymerizable substance is furfural alcohol and the solvent is ethanol.

12. The method according to claim 8, wherein the dielectric film has a capacitance density greater than a capacitance density of a pure thin film of the dielectric nanoparticles.

13. The method according to claim 8, wherein the substrate includes an electrode to which the first fluid is applied, the method further including applying an electrode to a side of the dielectric film opposite the substrate after the polymerizing step so that the dielectric film is a capacitor dielectric.

14. The method according to claim 13, wherein the applying-electrode step includes printing or evaporating electrode material onto the dielectric film.

15. The method according to claim 13, further including repeating the applying-layer, polymerizing, and applying-electrode steps to provide a multilayer dielectric structure with embedded conductors.

16. A dielectric film comprising nanoparticles and polymer material between at least some of the nanoparticles, the film having a capacitance change of within 0%-7% over the range 20° C.-125° C. and a dielectric constant between 17.5 and 25 for the range 100 Hz-1 MHz.

17. The dielectric film according to claim 16, further including electrodes disposed on opposite sides of the dielectric film.

18. The dielectric film according to claim 16, wherein the layer thickness is 200-400 nm, or approximately 1.4 μm.

19. The dielectric film according to claim 16, wherein the nanocrystals have diameters of approximately 30 nm.

20. The dielectric film according to claim 16, wherein at least some of the polymer material was formed by in-situ polymerization of a monomer disposed between at least some of the nanoparticles.
